(19) United States
(12) Patent Application Publication
(10) Pub. No.: US 2007/0290332 A1
(43) Pub. Date: Dec. 20, 2007

(54) Stacking structure of chip package

(75) Inventors: Tseng Shin Chiu, Hukou (TW); Chia-Yu Hung, Hukou (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/453,105

(22) Filed: Jun. 15, 2006

(51) Int. Cl. H01L 23/34

(52) U.S. Cl. 257/723

(57) ABSTRACT

A stacking structure of chip package disclosed herein includes a lead frame having a plurality of supporting fingers and a plurality of leads; a first chip arranged on one side of the lead frame by utilizing a first connecting element so as to partially cover these supporting fingers, wherein the supporting fingers stretch from the edge of the first chip toward the first chip to provide a support; a second chip arranged on the opposite side of the lead frame at the corresponding position of the first chip by utilizing a second connecting element to partially covering the supporting fingers, wherein the first chip, the second chip and the partially-covered supporting fingers are cooperated to define an open mold-flowing trench; an electrical-connecting element to electrically connect the first chip, the second chip and the leads; and a molding compound utilized to cover the first chip, the second chip, the electrical-connecting element and some of the lead frame, wherein the molding compound flows through the open mold-flowing trench to fully cover the first chip, the second chip and some of the supporting fingers. The supporting fingers are substituted for the die pad to get a better mold flowing in the molding process and so as to elevate process reliability.

### BACKGROUND OF THE INVENTION

1. Field of the Invention

The present invention relates to a chip package structure and more especially, relates to a stacking structure of chip package.

2. Description of the Prior Art

Along with the increasing of the aggregated density of the integrated circuit (IC) and the fast progress of the semi-conductor technology, the amount of the package leads become more and more. The package requirement of small package size, high process speed, and high package density has become the trend for the technology field of semi-conductor assembly.

Please refer to FIG. 1, the original stacking structure of chip package 10 includes a chip 11, a chip 12, a sticking pad 13, a plurality of conducting wires 14, a plurality of leads 15 and a molding compound 16. Wherein the chip 11, 12 are orderly stacked on the sticking pad 13, and the conducting wires 14 connect the chip 11,12 to the soldering pads 17 and leads 15. Therefore, the stacking structure of chip package 10 can be soldered on the circuit board by the exposed leads proceed the expected functions for each of the chip 11 and 12.

Most of the time it may need to assemble two chips with the same size, please refer to FIG. 2, which illustrates the stacking structure of the chip package 20 having two chips with the same size. It includes a chip 21, a chip 22, a cladding material 23, a plurality of conducting wires 24 and a plurality of leads 25; wherein the cladding material 23 is formed on the top surface of the chip 21 to cover some conducting wires 24 and then the chip 22 is arranged on the cladding material 23 and electrically connected to lead 25 by utilizing the conducting wires 24. However, within this package structure 20, the depth of the whole structure is increased due to the adding of the cladding material 23, and this disobeys the design trend such as the lightweight and thin shape of the electronic products. An improved method is provided, please refer to FIG. 3, the main features of the chip package structure 30 is to respectively paste two chips 31, 32 with the same size on the top surface and on the bottom surface of the sticking pad 33, and then to electrically connect the solder pads 36 of the chips 31, 32 to the leads 35 by utilizing the conducting wires 34. Therefore, the depth of the package structure is reduced. However, the package structure 30 has to assemble the conducting wires 34 and the chip 32 that attached on the top surface on the sticking pad 33 first, then attach the chip 31 on the bottom surface of the sticking pad 33 and the conducting wire 34. As this result, the package structure 30 needs to do the mold pressing two times to complete the package process, it will increase the time cost and the product failure rate.

### SUMMARY OF THE INVENTION

According to the issue mentioned previously, the present invention provides a structure of stacked-chip package.

One of objects of this invention is to provide a structure of stacked-chip package, the supporting fingers are substituted for the die pad can reduce the size of the touch area between the lead frame and the package to avoid the delaminating phenomenon caused from thermal stress.

Another object of this invention is to provide a structure of stacked-chip package, utilizing the supporting finger and chip to cooperate define an open mold-flowing trench so as to get the better mold flow when molding process. It may simply the process, raise the higher process reliability and reduce the cost.

Another object of this invention is to provide a stacking structure of the chip package which utilize the adhesive method to set up the chip, it has many merits such as being easier for the process, improving the production efficiency, increasing the product yield and reducing the depth of the package structure effectively.

Accordingly, one embodiment of the present invention provides a structure of stacked-chip package. It includes a lead frame having a plurality of supporting fingers and a plurality of leads; a first chip arranged on one side of the lead frame by utilizing a first connecting element so as to partially cover these supporting fingers, wherein these supporting fingers stretch from the edge of the first chip toward the first chip so as to provide a support; a second chip arranged on the opposite side of the position of the first chip of the lead frame by utilizing a second connecting element so as to partially cover there supporting fingers, wherein the first chip, the second chip ad the partially-covered supporting fingers cooperate to define an open mold-flowing trench; an electrical-connecting element electrically connected the first chip and the second chip with the leads; and a molding compound utilized to cover the first chip, the second chip, the electrical-connecting element and some of the lead frame, wherein the molding compound flows through the open mold-flowing trench to fully cover the first chip, the second chip and some of the supporting fingers.

These and other objects will appear more fully from the specification below.

### BRIEF DESCRIPTION OF THE DRAWINGS

FIG. 1 is a cross-sectional schematic diagram to illustrate the chip package structure according to a prior art;

FIG. 2 is a cross-sectional schematic diagram to illustrate the chip package structure according to another prior art;

FIG. 3 is a cross-sectional schematic diagram to illustrate the chip package structure according to another prior art;

FIG. 4A is a top plan-view schematic diagram to illustrate the stacking structure of the chip package in accordance with an embodiment of the present invention;

FIG. 4B is a detailed sectional-view schematic diagram of the portion indicated by the section lines A-A′ in FIG. 4A;

FIG. 5A is a top plan-view schematic diagram to illustrate the stacking structure of the chip package in accordance with another embodiment of the present invention; and

FIG. 5B is a detailed sectional-view schematic diagram of the portion indicated by the section lines B-B′ in FIG. 5A.

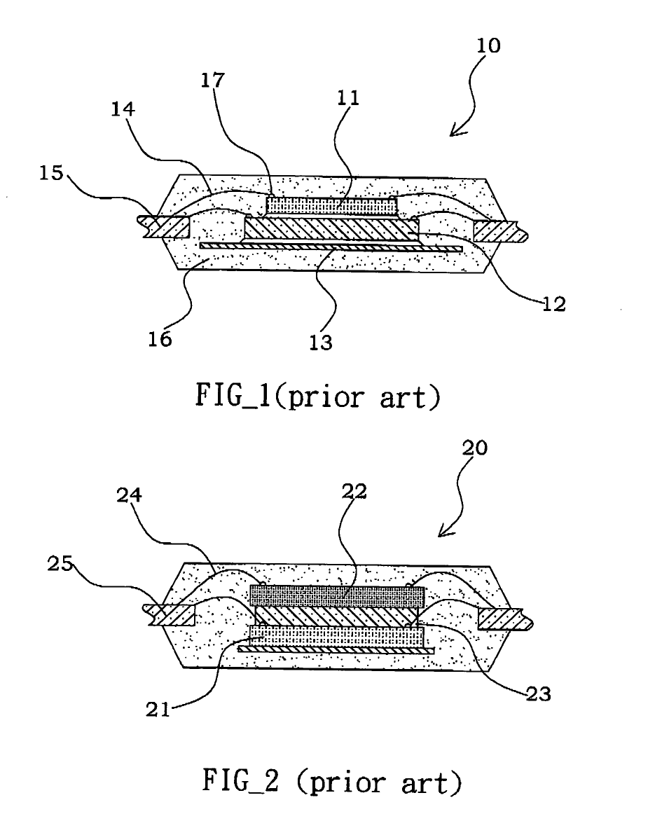

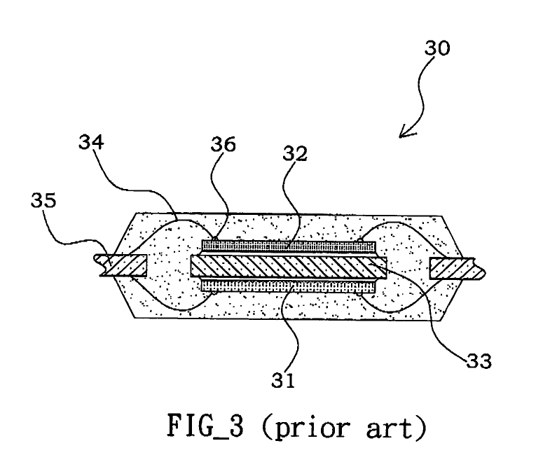

### DETAILED DESCRIPTION OF THE INVENTION

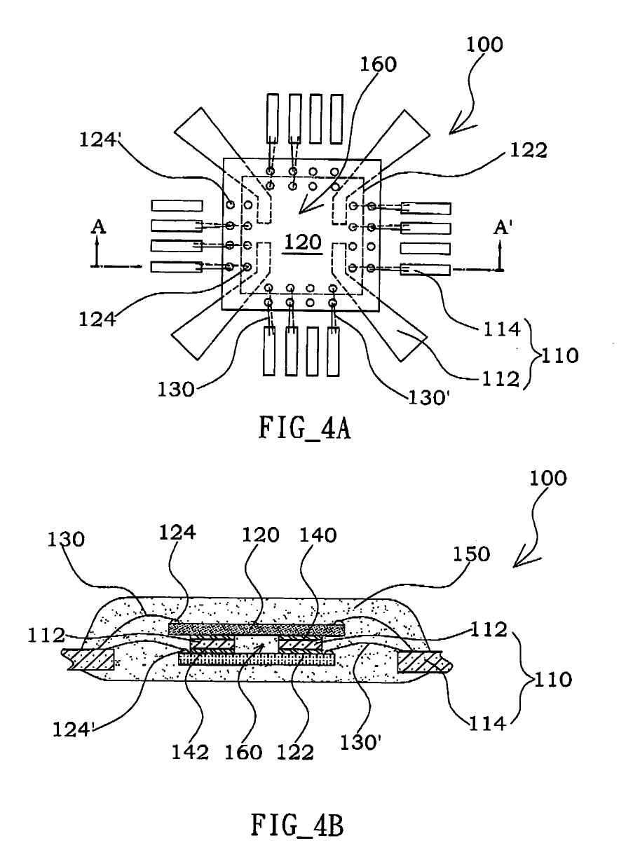

Please refer to FIG. 4A and FIG. 4B, are the top plan view and sectional view diagram illustrating the stacking structure of chip package in accordance with an embodiment of the present invention respectively. As shown in FIG. 4A, the stacking structure of chip package 100 includes a first chip 120, a second chip 122, a lead frame 110, an electrical-connecting element 130, 130′ and a molding compound 150 (shown in FIG. 4B). The lead frame 110 having a plurality of supporting fingers 112 and a plurality of leads 114; a first chip arranged on one side of the lead frame 110, such as the one side between the first chip 120 and the supporting finger 112, by utilizing a first connecting element with known skill, such as, plaster, and partially covered supporting finger 112 wherein the supporting finger 112 stretch from the edge of the first chip 120 toward the first chip 120 so as to provide a support. And a second chip 122 arranged on the opposite side of the position of the first chip 120 of the lead frame 110 by utilizing a second connecting element so as partially cover supporting finger 112 wherein the first chip 120, the second chip 122 and the partially covered supporting finger 112 are cooperate define an open mold-flowing trench 160 to simply the molding process after. And, exploiting the plaster method with connecting element can reduce the depth of the package structure 100 and the process difficulty. In one embodiment, the first connecting element and the second connecting element can be any one of the tape, the adhesive and the epoxy. The lead 114 is arranged on the edge in opposition to the first chip 120 and the second chip 122, even more, can arrange a plurality of solder pads 124, 124′ (shown in FIG. 4B) on the surface of the first chip 120 and the second chip 122 to simply electrical-connecting element 130, 130′ electrically connect to the lead 114. That said, the electrical-connecting element 130 electrically connected the solder pad 124 and lead 114 of the first chip 120, the electrical-connecting element 130′ electrically connected the solder pad 124′ and lead 114 of the second chip 122. In the embodiment, the electrical-connecting element 130, 130′ can be composed of a plurality of wires and electrically connected the first chip 120, the second chip 122 and the lead 114 by wire bonding. The material of the wires can composed of aurum (Au), copper (Cu) and aluminum (Al). Wherein the location, the size and the amount of the supporting fingers 112 and the solder pads 124, 124′ are not limited on this embodiment of the present invention, any other supporting mechanisms which can achieve the function of making the supporting fingers 112 of the lead frame 110 to stably sustain the first chip 120 and the second chip 122 are all covered in the filed of the present invention.

Accordingly, please refer to FIG. 4B, is a detailed sectional view of the portion indicated by the sectional lines A-A′ in FIG. 4A. The first chip 120 and the second chip 122 are arranged on two sides of the supporting finger 112 by the first connecting element 140 and the second connecting element 142 respectively, wherein the electrical-connecting element 130 and 130′, such as a plurality of wires, electrically connect the solder pad 124, 124′ and the lead 114 on the lead frame 110 of the first chip 120 and the second chip 122 by known skill, such as molding, cover the first chip 120, the second chip 122, electrical-connecting element 130, 130′ and some of the lead frame 110 by the molding compound 150 which is composed of epoxy. Wherein the molding compound 150 flows through the open mold-flowing trench 160 to fully cover the first chip 120 the second chip 122 and some of the supporting fingers 112. Due to the design of the open mold flow trench 160, the air becomes easier to exhaust, get the better mold flow when molding, as this result, the inner elements of the package structure 100 can be airtight separated from the outside pollution or attack. And the exposed part of the lead frame 110, such as some of leads 114, are soldering on the circuit board to further proceed the function of the first chip 120 and the second chip 122.

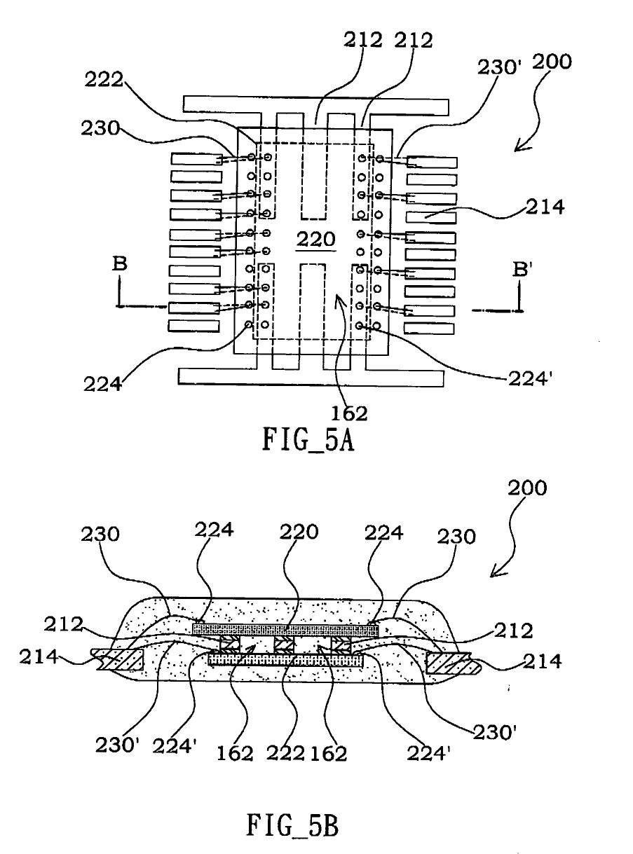

Please refer to FIG. 5A and FIG. 5B, which are the top plan-view and the sectional-view schematic diagrams to respectively illustrate the stacking structure of the chip package in accordance with another embodiment of the present invention. The difference between the present package structure 200 and the previous embodiment is the locations of the solder pads of the chip and the corresponding formation of the supporting fingers. Depending on the different function of the chip, the locations of the solder pads will be different. In this embodiment, the solder pad 224 and 224′ are located on two ends of the same side of the first chip 220 and the second chip 222, wherein the supporting finger 212 was designed as a comb structure with bar type, and the supporting finger 212 stretched from the two edges of the first chip 220, which don't have the solder pads 224 and 224′ on it, toward the first chip 220 to provide a support. The electrical-connecting element 230 is used to electrically connect the solder pad 224 of the first chip 220 and the lead 214, and the electrical-connecting element 230′ is used to electrically connect the solder pad 224′ of the second chip 222 and the lead 214′, wherein the first chip 220, the second chip 222 and some of the supporting fingers 212 are cooperated to define an open mold-flowing trench 162 to facilitate the proceeded molding process. The molding method is almost the same as which described in the previous embodiment, so it is not described here again. FIG. 5B is a detailed sectional-view schematic diagram schematic diagram of the portion indicated by the section lines B-B′ in FIG. 5A.

In addition, one of the characteristics of the present invention is to arrange the supporting fingers in different manners, depending on the different locations of the solder pads of the different functional chips. But in all manners, all the supporting fingers are stretched from the edge of the chip toward the chip to provide a support. By the way, another characteristic of the present invention is, the function and the size of two chips of the stacking structure of chip package can be the same or different. One another characteristic of the present invention is, utilizing the plaster method to arrange the chip stacked on the two sides of the supporting fingers can reduce the process difficulty and the depth of the package structure.

Accordingly, the stacking structure of chip package in accordance of the present invention is utilizing the supporting fingers to substitute for the die pad so as to facilitate the lead frame to sustain the chip by the supporting fingers. This way can dramatically reduce the touching area between the lead frame and the molding compound. Then utilizing the open mold-flowing trench, which defined as the chip and the supporting fingers, to get better mold flow when molding process and to decrease the thermal stress is caused by the different coefficient of thermal expansion between the lead frame and the molding compound. This can effectively avoid the delaminating phenomenon between the lead frame and the molding compound and so as to guaranty the product reliability. Besides, within the stacking structure of chip package, utilizing the adhesive method to set up the chip has many merits such as being easier for the process, improving the production efficiency, increasing the product yield and reducing the depth of the package structure effectively.

Although the present invention has been explained in relation to its preferred embodiment, it is to be understood that other modifications and variation can be made without departing the spirit and scope of the invention as hereafter claimed.

What is claimed is:

1. A stacking structure of chip package comprising:
a lead frame, having a plurality of supporting fingers and a plurality of leads;
a first chip, arranged on one side of said lead frame by utilizing a first connecting element and partially cover said plurality of supporting fingers, wherein said plurality of supporting fingers stretch from the edge of said first chip toward said first chip so as to provide a support;
a second chip, arranged on the opposite side of said lead frame at the corresponding the position of said first chip by utilizing a second connecting element, and partially covering said plurality of supporting fingers, wherein said first chip, said second chip and said partially-covered supporting fingers are cooperated to define an open mold-flowing trench;
an electrical-connecting element, to electrically connect said first chip, said second chip, and said plurality of leads; and
a molding compound utilized to cover said first chip, said second chip, said electrical-connecting element and some part of said lead frame, wherein said molding compound flows through said open mold-flowing trench to fully cover said first chip, said second chip and some of said plurality of supporting fingers.

2. A stacking structure of chip package according to claim 1, wherein said first connecting element located between said first chip and one side of said plurality of supporting fingers.

3. A stacking structure of chip package according to claim 1, wherein said second connecting element located between said second chip and another side of said plurality of supporting fingers.

4. A stacking structure of chip package according to claim 1, wherein said first connecting element is selected from any one of the tape and the adhesive.

5. A stacking structure of chip package according to claim 1, wherein said second connecting element is selected from any one of the tape and the adhesive.

6. A stacking structure of chip package according to claim 1, wherein said first connecting element is epoxy.

7. A stacking structure of chip package according to claim 1, wherein said second connecting element is epoxy.

8. A stacking structure of chip package according to claim 1, wherein said electrical-connecting element is composed of a plurality of wires.

9. A stacking structure of chip package according to claim 8, wherein the material of said plurality of wires composed of aurum (Au), copper (Cu) or aluminum (Al).

10. A stacking structure of chip package according to claim 1, further comprising a plurality of solder pads set on the surface of said first chip and said second chip.

11. A stacking structure of chip package according to claim 10, wherein said electrical-connecting element is electrically connected to said plurality solder pads set on said first chip and said second chip.

12. A stacking structure of chip package according to claim 1, wherein said molding compound is composed of epoxy.

13. A stacking structure of chip package according to claim 1, wherein said plurality of leads are arranged on one edge in opposition to said first chip and said second chip.

14. A stacking structure of chip package according to claim 1, wherein said plurality of supporting fingers are stretched from the edge of said first chip toward said first chip to form a comb structure.
